(19) United States
(12) Patent Application Publication
(10) Pub. No.: US 2015/0054383 A1
(43) Pub. Date: Feb. 26, 2015

(54) CONTROL DEVICE USING BUTTONS AND CONTROL METHOD THEREOF

(71) Applicant: SAMSUNG ELECTRONICS CO., LTD., Suwon-si (KR)

(72) Inventor: Young-chul KANG, Suwon-si (KR)

(73) Assignee: SAMSUNG ELECTRONICS CO., LTD., Suwon-si (KR)

(21) Appl. No.: 14/211,618

(22) Filed: Mar. 14, 2014

(30) Foreign Application Priority Data
Aug. 26, 2013 (KR) 10-2013-0101209

(51) Int. Cl. H01L 41/113; H01L 41/04

(52) U.S. Cl. CPC H01L 41/1132; H01L 41/042
USPC 310/319

(57) ABSTRACT

A control device includes a piezoelectric element; a plurality of buttons that are placed in a position corresponding to the piezoelectric element and are configured to apply different pressures, relative to each other, to the piezoelectric element; a controller configured to, if an electric signal of a size corresponding to the pressure is output from the piezoelectric element, determine which button of the plurality of buttons is selected depending on the size of the electric signal; and an output unit configured to output a control signal corresponding to the selected button.

### CROSS-REFERENCE TO RELATED APPLICATIONS

This application claims priority from Korean Patent Application No. 2013-0101209 filed Aug. 26, 2013 in the Korean Intellectual Property Office, the disclosure of which is incorporated herein by reference in its entirety.

### BACKGROUND

1. Field

Apparatuses and methods consistent with exemplary embodiments relate to a control device using buttons and a control method thereof. More particularly, the present disclosure relates to a control device using a piezoelectric element and a control method thereof.

2. Description of the Related Art

Thanks to the development of electronic technology, various electronic products are being used. These electronic products can be controlled by a control device mounted in a main body thereof or a control device provided separately from the electronic products.

Such a control device may include remote control devices such as a remote controller. The control device is provided with an input member that a user can choose. The input member may include various members such as a touch screen, a wheel button, a microphone, a camera, etc., but buttons that the user can press are most commonly used. In a case in which the control device is implemented as a remote controller, when the user presses a button provided in the remote controller, the remote controller sends a remote signal corresponding to the button to an external device. Accordingly, the external device performs an operation corresponding to the remote signal.

As described above, because the control device sends a remote signal according to a button selected, the control device needs to have power required to perform operations to recognize whether the button is selected, to generate remote signals, and to transmit the remote signals. Accordingly, the control device generally uses batteries. However, there is inconvenience that the batteries should be replaced or recharged periodically. In addition, environmental pollution caused by waste batteries may be generated.

Therefore, the need for a control device to solve these problems has emerged.

### SUMMARY

The present disclosure has been developed in order to overcome the above drawbacks and other problems associated with the conventional arrangement. An aspect of the present disclosure is to provide a control device that can recognize a button selected by a user by using a piezoelectric element and perform a control operation corresponding to the selected button and a control method thereof.

The above aspect and/or other feature of the present disclosure can substantially be achieved by providing a control device, which may include a piezoelectric element; a plurality of buttons that are placed in a position corresponding to the piezoelectric element and are configured to apply different pressures, relative to each other in size to the piezoelectric element; a controller configured to, if an electric signal of a size corresponding to a pressure output from the piezoelectric element, determine which button of the plurality of buttons is selected depending on the size of the electric signal; and an output unit configured to output a control signal corresponding to the selected button.

The control device may include a transformer configured to, if the electric signal is input from the piezoelectric element, convert the electric signal into a voltage of a level corresponding to the size of the electric signal, and apply the voltage to the controller; and a storage which is configured to pre-store a voltage level for each of the plurality of buttons, wherein the controller may be activated by the voltage applied from the transformer, and determines the selected button among the plurality of buttons by comparing a plurality of voltage levels stored for each of the plurality of buttons and a voltage level of the voltage applied from the transformer.

The controller may generate the control signal by using a frequency corresponding to the selected button, and output the control signal through the output unit.

The control device may include a body portion comprising a plurality of holes, wherein the plurality of buttons may be mounted in the plurality of holes in a first surface direction of the body portion, respectively, and the piezoelectric element may be mounted to correspond to the plurality of holes in a second surface direction of the body portion, and each of the plurality of buttons may include a contacting portion that a user touches; and an extending portion that is extended from the contacting portion and is connectable to the piezoelectric element through one of the plurality of holes.

The control device may include a plurality of elastic members that is placed inside of the plurality of holes, respectively, and provides restoring force to the plurality of buttons, wherein the contacting portion provided in each of the plurality of buttons may be spaced apart a same distance from a first surface of the body portion in a vertical direction, and, when each of the plurality of buttons is pushed, the contacting portion may be in contact with the first surface, thereby causing each of the buttons to be pushed to a same depth.

The extending portion provided in each of the plurality of buttons may have areas differing from each other.

The control device may include a plurality of protrusions that correspond to the plurality of holes on a surface of the piezoelectric element and are different from each other in size, wherein if each of the protrusions touches the extending portion provided on each of the plurality of buttons, pressures different from each other in size may be applied to the piezoelectric element.

The control device may include an elastic member placed between the extending portion provided on each of the plurality of buttons and the piezoelectric element.

According to another aspect of the present disclosure, a control method of a control device may include outputting an electric signal with a size corresponding to pressure being applied to the piezoelectric element; determining which button of the plurality of buttons is selected depending on a size of the electric signal; and outputting a control signal corresponding to the selected button.

The control method may include pre-storing a voltage level for each of the plurality of buttons.

The voltage level may be generated when pressure is applied to the piezoelectric element.

The control device further comprises: vertically provided body portions and horizontally provided bottom supporting portions, wherein the vertically provided body portions and horizontally provided bottom supporting portions together form first hole entrances in which the plurality of buttons are mounted and second hole entrances to which the piezoelectric element is mounted.

The first hole entrances have cross-sectional areas larger than the corresponding second hole entrances.

Each of the plurality of buttons comprises: a contacting portion that a user touches; and an extending portion that is extendable from the contacting portion to the piezoelectric element through the corresponding first hole entrance and the corresponding second hole entrance.

The extending portion contacts the piezoelectric element via respective elastic members provided between the extending portion and the piezoelectric element.

The control method further comprises selecting at least one of the plurality of buttons that correspond to the piezoelectric element, wherein each of the plurality of buttons apply pressures different from each other in size to the piezoelectric element.

The determining operation may comprise comparing a plurality of voltage levels stored for each of the plurality of buttons.

The voltage level for each of the plurality of buttons may be stored in a storage of the control device.

According to various embodiments of the present disclosure, because they can determine whether a button is selected by using a piezoelectric element, user convenience and efficiency of the device may be improved.

Other objects, advantages and salient features of the present disclosure will become apparent from the following detailed description, which, taken in conjunction with the annexed drawings, discloses preferred embodiments.

### BRIEF DESCRIPTION OF THE DRAWINGS

These and/or other aspects and advantages of the present disclosure will become apparent and more readily appreciated from the following description of the embodiments, taken in conjunction with the accompanying drawings of which:

FIG. 1 is a block diagram illustrating a control device according to an exemplary embodiment of the present disclosure;

FIG. 2 is a block diagram illustrating a control device according to another exemplary embodiment of the present disclosure;

FIGS. 3 to 7 are views illustrating a shape of a piezoelectric element and a plurality of buttons according to various exemplary embodiments of the present disclosure;

FIG. 8 is a flowchart illustrating a control method of a control device according to an exemplary embodiment of the present disclosure; and

FIG. 9 is a schematic diagram illustrating a control device according to an exemplary embodiment of the present disclosure.

Throughout the drawings, like reference numerals will be understood to refer to like parts, components and structures.

### DETAILED DESCRIPTION OF THE EXEMPLARY EMBODIMENTS

Hereinafter, certain exemplary embodiments of the present disclosure will be described in detail with reference to the accompanying drawings.

The matters defined herein, such as a detailed construction and elements thereof, are provided to assist in a comprehensive understanding of this description. Thus, it is apparent that exemplary embodiments may be carried out without those defined matters. Also, well-known functions or constructions are omitted to provide a clear and concise description of exemplary embodiments. Further, dimensions of various elements in the accompanying drawings may be arbitrarily increased or decreased for assisting in a comprehensive understanding.

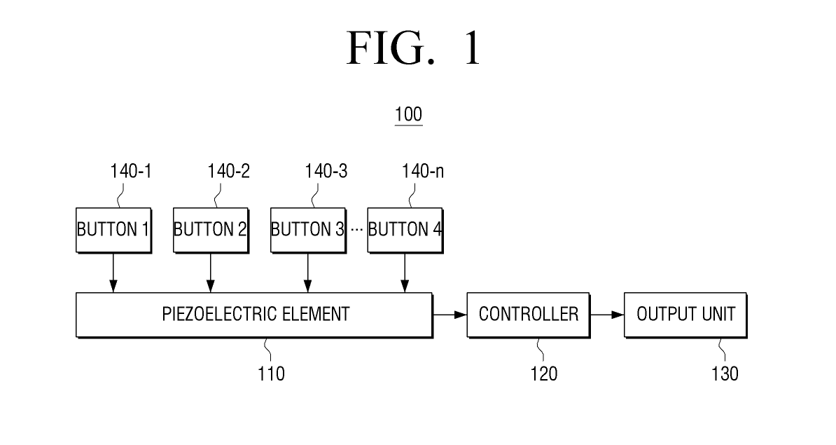

FIG. 1 is a block diagram illustrating a control device according to an exemplary embodiment of the present disclosure.

Referring to FIG. 1, a control device 100 may include a piezoelectric element 110, a controller 120, an output unit 130, a plurality of buttons 140-1, 140-2, 140-3, and 140-n.

The control device 100 refers to an apparatus that can control operations of other devices. In detail, the control device 100 may be implemented as a remote controller to control operations of various external devices such as a TV, an air conditioner, an audio system, a personal computer, etc. or a button operation panel mounted in a main body of each of electronic products.

The piezoelectric element 110 is a component that, if pressure is applied thereto in a predetermined direction from the outside, outputs an electrical signal corresponding to the pressure.

The plurality of buttons 140-1, 140-2, 140-3, and 140-n is placed in a position corresponding to the piezoelectric element 110. In detail, a single piezoelectric element is placed in an overall area of bottom sides of the plurality of buttons 140-1, 140-2, 140-3, and 140-n. Accordingly, the plurality of buttons 140-1, 140-2, 140-3, and 140-n can commonly use the single piezoelectric element. The plurality of buttons 140-1, 140-2, 140-3, and 140-n may apply pressures different from each other in size to the piezoelectric element 110, respectively. In detail, if a user selects and pushes one of the pluralities of buttons 140-1, 140-2, 140-3, and 140-n, the selected button presses the piezoelectric element 110 so that the pressure is applied to the piezoelectric element 110. Accordingly, the piezoelectric element 110 may output an electric signal which is proportional to the pressure. The electric signal is provided to the controller 120.

If the electric signal with a size corresponding to the pressure is output from the piezoelectric element 110, the controller 120 may be activated by the electric signal. The activated controller 120 may determine which button of the plurality of buttons 140-1, 140-2, 140-3, and 140-n is selected by the user depending on the size of the electric signal. The controller 120 generates a control signal to perform an operation corresponding to the determined button, and then outputs the control signal through the output unit 130.

If the control signal is provided from the controller 120, the output unit 130 may transmit the provided control signal to other apparatus.

According to exemplary embodiments, the output unit 130 may transmit the control signal to other apparatus by using a variety of communication methods. For example, the control device 100 may use the infrared communication. Alternatively, if the accumulation of electrical energy generated in the piezoelectric element 110 is enough, the output unit 130 may output the control signal by using a wireless communication method such as Bluetooth, Zigbee, RF communication, etc. On the other hand, if the control device 100 is formed to be mounted in the main body of the product, the output unit 130 may be connected to a main controller (not illustrated) of the product through a wired interface.

The electronic device (not illustrated) may perform a command corresponding to the control signal by receiving the control signal from the output unit 130.

FIG. 1 illustrates that four buttons share a single piezoelectric element; however, the number of the buttons may be implemented in various ways.

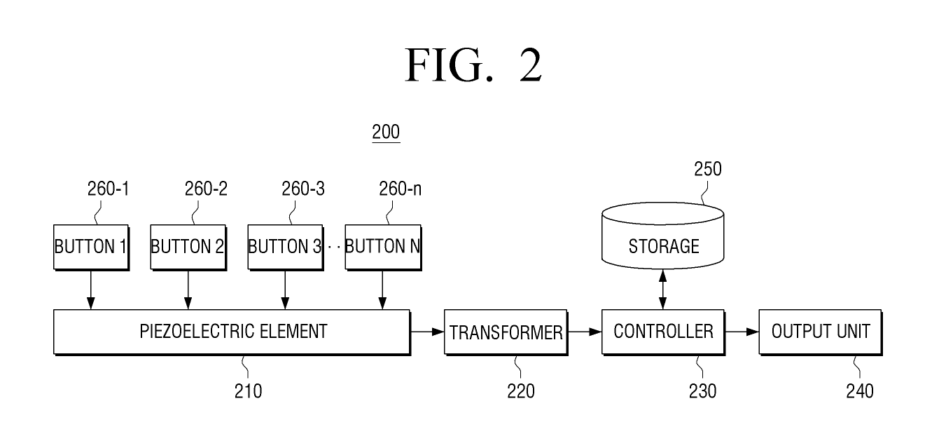

FIG. 2 is a block diagram illustrating a control device according to another exemplary embodiment of the present disclosure.

Referring to FIG. 2, the control device 200 may include a piezoelectric element 210, a transformer 220, a controller 230, an output unit 240, a storage 250, a plurality of buttons 260-1, 260-2, 260-3, and 260-n.

The piezoelectric element 210, the output unit 240, and the plurality of buttons 260-1, 260-2, 260-3, and 260-n are the same as the exemplary embodiment disclosed in FIG. 1; therefore, duplicate descriptions thereof will be omitted.

The transformer 220 receives an electric signal from the piezoelectric element 110, converts the electric signal into a voltage of a level corresponding to the size of the electric signal, and then applies the transformed voltage to the controller 230.

Then, the storage 250 may store voltage levels that are generated when each of the plurality of buttons 260-1, 260-2, 260-3, and 260-n applies the pressure to the piezoelectric element 110.

In detail, the storage 250 may store identification information corresponding to each of the plurality of buttons 260-1, 260-2, 260-3, and 260-n and voltage level corresponding to it by mapping them. The identification information may include a serial number, button location information, etc. Also, the controller 230 is activated by the voltage applied from the transformer 220, and may determine which button of the plurality of buttons 260-1, 260-2, 260-3, and 260-n is selected by the user by comparing a plurality of voltage levels stored in the storage 250 for each of the plurality of buttons and the voltage level being applied from the transformer 220. Because the controller 230 can be activated by the electric signal generated by the piezoelectric element, the controller 230 may perform the control operation without a separate battery.

Further, the controller 230 may be formed so that it generates control signals by using frequencies corresponding to the plurality of buttons 260-1, 260-2, 260-3, and 260-n, and outputs the control signals through the output unit 240. As described above, the plurality of buttons may apply pressures different from each other in size to a single piezoelectric element. Hereinafter, various examples with respect to the shapes of the buttons to apply pressures different from each other in size will be described.

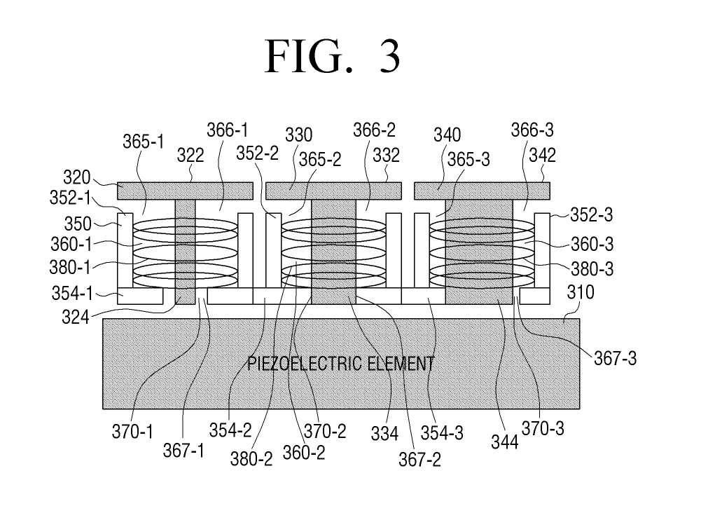

FIG. 3 illustrates a shape of the plurality of buttons and a piezoelectric element according to an exemplary embodiment of the present disclosure.

FIG. 3 shows a case in which three buttons 320, 330, and 340 use a single piezoelectric element 310. According to FIG. 3, the control device 100 includes a body portion 350 containing a plurality of holes 360-1, 360-2 and 360-3. The body portion 350 is a component to support the plurality of buttons 320, 330, and 340 and the piezoelectric element 310. The plurality of holes 360-1, 360-2 and 360-3 is formed the same as the number of buttons and in positions of the buttons 320, 330, and 340. The plurality of holes 360-1, 360-2 and 360-3 passes through the body portion 350.

As illustrated in FIG. 3, first direction hole-entrances 365-1, 365-2, and 365-3 in which the buttons 320, 330, and 340 are mounted have a cross-sectional area larger than second direction hole-entrances 370-1, 370-2, and 370-3 in which the piezoelectric element 310 is mounted.

Each of the buttons 320, 330, and 340 is mounted in each of the holes 360-1, 360-2 and 360-3 from each of the first direction hole-entrances 365-1, 365-2, and 365-3 to orient each of extending portions 324, 334, and 344 toward each of the second direction hole-entrances 370-1, 370-2, and 370-3. However, the piezoelectric element 310 is mounted to correspond to the entire of the plurality of holes 360-1, 360-2 and 360-3 in the second direction hole-entrances 370-1, 370-2, and 370-3 of the body portion 350. A first surface 366-1, 366-2, and 366-3 of the body portion 350 is near the first direction hole-entrances 365-1, 365-2, and 365-3, and a second surface 367-1, 367-2, and 367-3 thereof is near the second direction hole-entrances 370-1, 370-2, and 370-3. Also, elastic members 380-1, 380-2, and 380-3 are placed between contacting portions 322, 332, and 342 of the buttons 320, 330, and 340 and bottom supporting portions 354-1, 354-2, and 354-3 inside the holes 360-1, 360-2 and 360-3, respectively. As the user presses and then releases the buttons 320, 330, and 340, each of the elastic members 380-1, 380-2, and 380-3 provides restoring force to each of the buttons 320, 330, and 340, thereby allowing each of the buttons 320, 330, and 340 to return to an original position.

Also, the contacting portions 322, 332, and 342 are formed to be touched by the user, spaced apart the same distance from the first surfaces 366-1, 366-2, and 366-3 of the body portion 350 in a vertical direction, and in contact with the first surface 366-1, 366-2, and 366-3 of the body portion 350 when each of the buttons 320, 330, and 340 is pushed. Then, each of the extending portions 324, 334, and 344 are extended from each of the contacting portions 322, 332, and 342 and may be connected to the piezoelectric element 310 through the holes 360-1, 360-2 and 360-3.

On the other hand, the extending portions 324, 334, and 344 of the buttons 320, 330, and 340 are provided in the form of a pillar having a cross-sectional area different from each other, respectively. Accordingly, as each of the buttons 320, 330, and 340 is pressed, the corresponding extending portion 324, 334, and 344 passes through the second direction hole-entrance 370-1, 370-2, and 370-3, and then presses the piezoelectric element 310. Because the extending portions 324, 334, and 344 have cross-sectional areas different from each other, although the user presses each button 320, 330, and 340 with equal force, the pressure that is applied to the piezoelectric element 310 will be different. Accordingly, the piezoelectric element 310 outputs an electric signal having a different size for each of the buttons 320, 330, and 340, and thus the controller 120 may determine which button 320, 330, or 340 is selected based on the size of the electric signal.

As illustrated in FIG. 3, the size of each of the contacting portions 322, 332, and 342 of the buttons 320, 330, and 340 is larger than the size of each of the first direction hole-entrances 365-1, 365-2, and 365-3. Accordingly, when the user presses each of the buttons with strong force, the contacting portion 322, 332, and 342 of each of the buttons 320, 330, and 340 is in contact with the body portion 350 around the first direction hole-entrances 365-1, 365-2, and 365-3 so that the button is no longer pressed. Accordingly, even if the user presses one button with different force, the button may deliver the same pressure to the piezoelectric element 310.

In FIG. 3, the body portion 350 is illustrated and explained to be formed in a single body. However, the body portion 350 may be divided into a plurality of body portions based on the holes. In this case, each of the body portions may consist of a side wall 352-1, 352-2, or 352-3 and a bottom support member 354-1, 354-2, or 354-3. The configuration of the body portion according to such embodiment will not be illustrated.

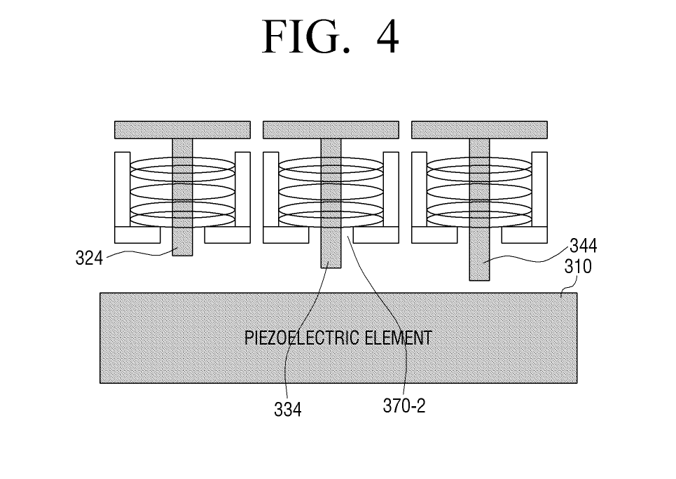

FIG. 4 illustrates a shape of pluralities of buttons and a piezoelectric element according to another exemplary embodiment of the present disclosure. Description duplicated with the exemplary embodiment of FIG. 3 will be omitted.

According to FIG. 4, extending portions 324, 334, and 344 of the buttons 320, 330, and 340 may have lengths different from each other. There may be difference between the pressures which the extending portions 324, 334, and 344 of the buttons 320, 330, and 340 apply to the piezoelectric element 310 by allowing each of the extending portions 324, 334, and 344 of the buttons 320, 330, and 340 to have a different length. In other words, the user may adjust the intensity of the pressure which each of the buttons 320, 330, and 340 applies to the piezoelectric element 310.

In this case, an end of each of the extending portion 324, 334, and 344 of the buttons 320, 330, and 340 may be placed below the second surfaces 367-1, 367-2, and 367-3 of the body portion 350.

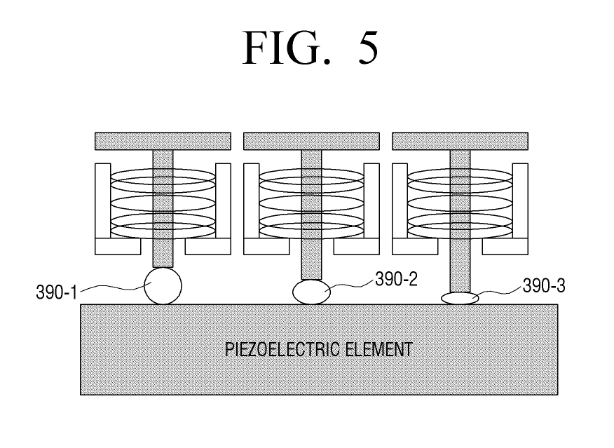

FIG. 5 illustrates a shape of the plurality of buttons and a piezoelectric element according to another exemplary embodiment of the present disclosure.

According to FIG. 5, the exemplary embodiment of FIG. 5 is similar to the exemplary embodiment of FIG. 4 The difference from FIG. 4 is that FIG. 5 further includes elastic members 390-1, 390-2, and 390-3 corresponding to the buttons 320, 330, and 340 between the extending portions 324, 334, and 344 of the buttons 320, 330, and 340 and the piezoelectric element 310.

In this case, the elastic members 390-1, 390-2, and 390-3 may be formed of a rubber, a spring, etc. The elastic members 390-1, 390-2, and 390-3 allows each of the extending portions 324, 334, and 344 of the buttons 320, 330, and 340 to effectively apply the pressure to the piezoelectric element 310.

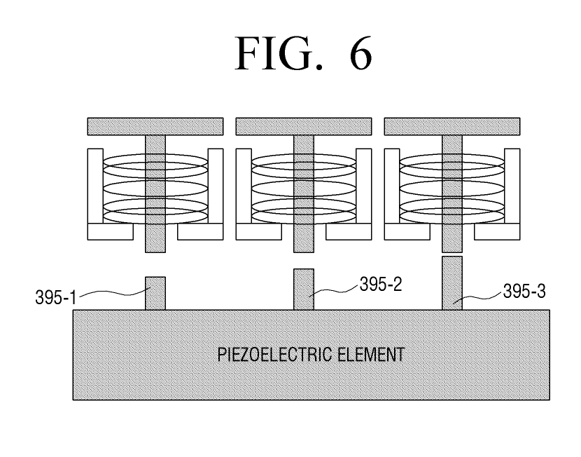

FIG. 6 illustrates a shape of pluralities of buttons and a piezoelectric element according to another exemplary embodiment of the present disclosure.

According to FIG. 6, the lengths of the extending portions 324, 334, and 344 of the buttons 320, 330, and 340 may be the same as or different from each other. Also, the areas of the extending portions 324, 334, and 344 of the buttons 320, 330, and 340 may be the same as or different from each other.

However, in FIG. 6, for example, a case in which the lengths and areas of the extending portions 324, 334, and 344 of the buttons 320, 330, and 340 are the same will be described.

As illustrated in FIG. 6, a plurality of protrusions 395-1, 395-2, and 395-3 may be placed on the top surface of the piezoelectric element 310. The protrusions 395-1, 395-2, and 395-3 may be formed of the piezoelectric element 310. Alternatively, any material, if it can deliver pressure well, may be used as the protrusions 395-1, 395-2, and 395-3.

On the other hand, if the protrusions 395-1, 395-2, and 395-3 are placed on the top surface of the piezoelectric element 310, each of the buttons 320, 330, and 340 corresponding to the piezoelectric element 310 may differently deliver pressure from each other to the piezoelectric element 310, somewhat similar to how the configuration that the extending portions 324, 334, and 344 of the buttons 320, 330, and 340 have lengths different from each other.

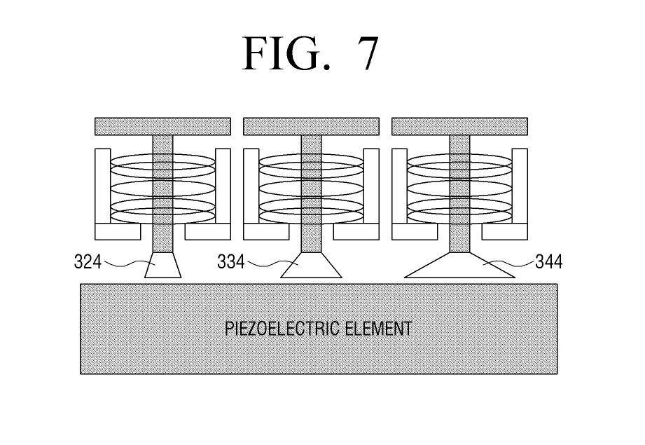

FIG. 7 illustrates a shape of the plurality of buttons and a piezoelectric element according to another exemplary embodiment of the present disclosure.

According to FIG. 7, because the ends of the extending portions 324, 334, and 344 of the buttons 320, 330, and 340 are configured to have areas different from each other, the buttons 320, 330, and 340 may apply pressures different from each other to the piezoelectric element 310.

At this time, the lengths of the extending portions 324, 334, and 344 of the buttons 320, 330, and 340 may be the same as each other. Alternatively, the lengths of the extending portions 324, 334, and 344 of the buttons 320, 330, and 340 may be different from each other.

In FIGS. 3 to 7, the shape of the plurality of buttons and the piezoelectric element has been described. The geometric features as described above may be shared. For example, each of the extending portions 324, 334, and 344 of the buttons 320, 330, and 340 may be formed to be different in both length and area.

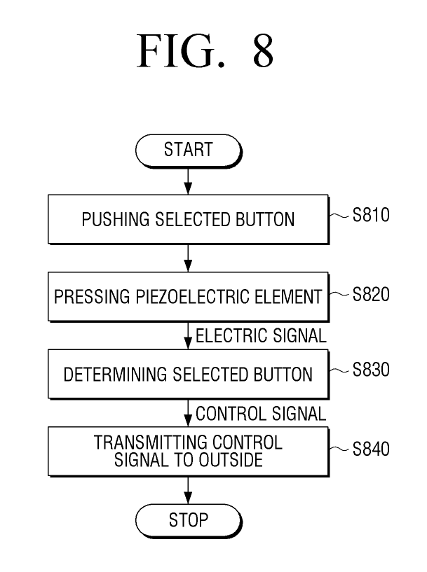

FIG. 8 is a flowchart illustrating a control method of a control device according to an exemplary embodiment of the present disclosure.

According to FIG. 8, a control method of a control device according to an exemplary embodiment of the present disclosure may be configured as follows.

In detail, a selected button is pushed by a user (S810), and if the button is pushed, pressure is applied to a piezoelectric element (S820). In this case, the piezoelectric element transmits an electric signal corresponding to the applied pressure to a controller, and then the controller determines the selected button (S830). Depending on the determined results, the controller sends a control signal to the outside through an output unit (S840).

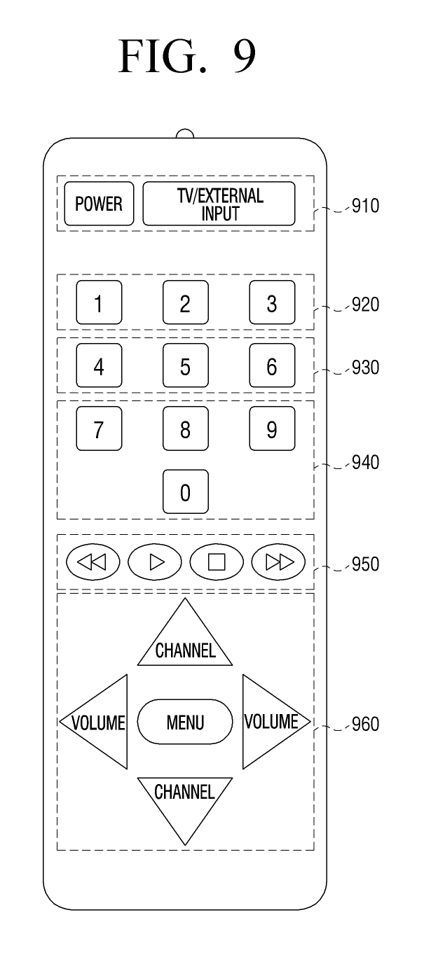

FIG. 9 is a schematic diagram illustrating a control device according to an exemplary embodiment of the present disclosure.

According to FIG. 9, the control device may be configured so that a single piezoelectric element corresponds to a single group formed by grouping a plurality of buttons. For example, a power button and TV/external input button group 910 corresponds to a single piezoelectric element, and a button 1, 2, 3 group 920 also corresponds to a single piezoelectric element. If a button 1 is pushed, the pressure is applied to the piezoelectric element, and then a voltage of a level corresponding to the pressure is generated, thereby sending an electric signal to a controller (not illustrated). The buttons 2 and 3 are likewise.

The controller (not illustrated) may generate a control signal through the electric signal of the selected button, and may transmit the control signal to the outside through an output unit (not illustrated). At this time, the control device may be configured to include a storage (not illustrated) in which voltage levels are pre-stored.

As the power button and TV/external input button group 910 and the button 1, 2, 3 group 920 each correspond to a single piezoelectric element, each of the rest of the plurality of button groups 930, 940, 950, and 960 corresponds to a single piezoelectric element and operates as described above. Therefore, a detailed description thereof will be omitted.

While the exemplary embodiments of the present disclosure have been described, additional variations and modifications of the exemplary embodiments may occur to those skilled in the art once they learn of the basic inventive concepts. Therefore, it is intended that the appended claims shall be construed to include both the above exemplary embodiments and all such variations and modifications that fall within the spirit and scope of the inventive concepts.

What is claimed is:

1. A control device comprising:
a piezoelectric element;
a plurality of buttons that are placed in a position corresponding to the piezoelectric element and are configured to apply different pressures, relative to each other, to the piezoelectric element;
a controller configured to, if an electric signal of a size corresponding to a pressure output from the piezoelectric element, determine which button of the plurality of buttons is selected depending on the size of the electric signal; and
an output unit configured to output a control signal corresponding to the selected button.

2. The control device of claim 1, further comprising:
a transformer configured to, if the electric signal is input from the piezoelectric element, convert the electric signal into a voltage of a level corresponding to the size of the electric signal, and apply the voltage to the controller; and
a storage which is configured to pre-store a voltage level for each of the plurality of buttons,
wherein the controller is activated by the voltage applied from the transformer, and determines the selected button among the plurality of buttons by comparing a plurality of voltage levels stored for each of the plurality of buttons and a voltage level of the voltage applied from the transformer.

3. The control device of claim 2, wherein
the controller generates the control signal by using a frequency corresponding to the selected button, and outputs the control signal through the output unit.

4. The control device of claim 1, further comprising:
a body portion comprising a plurality of holes,
wherein the plurality of buttons are mounted in the plurality of holes in a first surface direction of the body portion, respectively, and the piezoelectric element is mounted to correspond to the plurality of holes in a second surface direction of the body portion, and
each of the plurality of buttons comprises,
a contacting portion that a user touches; and
an extending portion that is extended from the contacting portion and is connectable to the piezoelectric element through one of the plurality of holes.

5. The control device of claim 4, further comprising:
a plurality of elastic members that are placed inside of the plurality of holes, respectively, and provides restoring force to the plurality of buttons,
wherein the contacting portion provided in each of the plurality of buttons is spaced apart a same distance from a first surface of the body portion in a vertical direction, and, when each of the plurality of buttons is pushed, the contacting portion is in contact with the first surface, thereby causing each of the buttons to be pushed to a same depth.

6. The control device of claim 5, wherein
the extending portion provided in each of the plurality of buttons have areas differing from each other.

7. The control device of claim 5, wherein
the extending portion provided in each of the plurality of buttons have lengths differing from each other.

8. The control device of claim 4, further comprising:
a plurality of protrusions that correspond to the plurality of holes on a surface of the piezoelectric element and are different from each other in size,
wherein if each of the protrusions touches the extending portion provided on each of the plurality of buttons, pressures different from each other in size are applied to the piezoelectric element.

9. The control device of claim 7, further comprising:
an elastic member placed between the extending portion provided on each of the plurality of buttons and the piezoelectric element.

10. A control method of a control device comprising:
outputting an electric signal with a size corresponding to pressure being applied to a piezoelectric element;
determining which button of a plurality of buttons is selected depending on the size of the electric signal; and
outputting a control signal corresponding to the selected button.

11. The control method of claim 10, further comprising pre-storing a voltage level for each of the plurality of buttons.

12. The control method of claim 11, wherein the voltage level is generated when pressure is applied to the piezoelectric element.

13. The control device of claim 2, wherein the voltage level is generated when pressure is applied to the piezoelectric element.

14. The control device of claim 1, further comprising:
vertically provided body portions and horizontally provided bottom supporting portions,
wherein the vertically provided body portions and horizontally provided bottom supporting portions together form first hole entrances in which the plurality of buttons are mounted and second hole entrances to which the piezoelectric element is mounted.

15. The control device of claim 14, wherein the first hole entrances have cross-sectional areas larger than the corresponding second hole entrances.

16. The control device of claim 14, wherein each of the plurality of buttons comprises:
a contacting portion that a user touches; and
an extending portion that is extendable from the contacting portion to the piezoelectric element through the corresponding first hole entrance and the corresponding second hole entrance.

17. The control device of claim 16, wherein the extending portion contacts the piezoelectric element via respective elastic members provided between the extending portion and the piezoelectric element.

18. The control method of claim 10, further comprising selecting at least one of the plurality of buttons that correspond to the piezoelectric element, wherein each of the plurality of buttons apply pressures different from each other in size to the piezoelectric element.

19. The control method of claim 11, wherein the determining comprises comparing a plurality of voltage levels stored for each of the plurality of buttons.

20. The control method of claim 19, wherein the voltage level for each of the plurality of buttons is stored in a storage of the control device.
